(19) United States
(12) Patent Application Publication
(10) Pub. No.: US 2015/0097163 A1
(43) Pub. Date: Apr. 9, 2015

(54) SEMICONDUCTOR DEVICE, DISPLAY, AND METHOD OF MANUFACTURING SEMICONDUCTOR DEVICE

(71) Applicant: Sony Corporation, Tokyo (JP)

(72) Inventors: Michihiro Kanno, Kanagawa (JP); Takahiro Kawamura, Kanagawa (JP); Hiroshi Inamura, Tottori (JP)

(21) Appl. No.: 14/395,676

(22) PCT Filed: Apr. 15, 2013
(86) PCT No.: PCT/JP2013/061697

§ 371 Date: Oct. 20, 2014

(30) Foreign Application Priority Data
Apr. 26, 2012 (JP) 2012-100543

(51) Int. Cl. H01L 51/05; H01L 29/423; H01L 27/28; H01L 29/786; H01L 27/12

(52) U.S. Cl. CPC H01L 51/0545; H01L 29/7869; H01L 27/1225; H01L 27/1259; H01L 27/283; H01L 29/42384
USPC 257/40; 257/43; 438/158

(57) ABSTRACT

A semiconductor device includes: a gate electrode layer; a gate insulating film provided on the gate electrode layer; a semiconductor layer provided, in opposition to the gate electrode layer, on the gate insulating film; and a source-drain electrode layer provided on the semiconductor layer and on the gate insulating film. A face, in opposition to the gate insulating film, of the semiconductor layer is located above a face of a section, located on the gate insulating film, of the source-drain electrode layer.

### TECHNICAL FIELD

The technology relates to a semiconductor device, a display, and a method of manufacturing the semiconductor device.

### BACKGROUND ART

A flat-panel display including a liquid crystal display, an organic electroluminescence (EL) display, or the like utilizes a passive matrix scheme or an active matrix scheme in order to drive a panel. The active matrix scheme is of a type in which a thin-film transistor (TFT) is provided for each pixel, and the TFTs control light and dark of the respective pixels. Such active matrix scheme has been the mainstream in recent years because of its higher display quality than that of the passive matrix scheme.

As for the TFT, a staggered structure or an inverted-staggered structure is used. The staggered structure is of a type in which a channel region and a source-drain region are formed in respective semiconductor layers that are different from each other. The inverted-staggered structure, or a bottom gate structure, is of a type in which a gate electrode layer is located below the source-drain region in cross-section of the aforementioned staggered structure. For example, reference is made to Japanese Unexamined Patent Application Publication No. 2012-53463 (JP2012-53463A).

### CITATION LIST

### Patent Literature

PTL 1: Japanese Unexamined Patent Application Publication No. 2012-53463

### SUMMARY

For example, in the TFT having the inverted-staggered structure disclosed in JP2012-53463A, an electric field is intense at an intersection, on a gate insulating film 402, of a microcrystalline semiconductor region 133a (semiconductor layer) in a semiconductor multilayer 133 and source-drain electrodes 405a and 405b. Such electric field generates a carrier between a drain and a channel of the microcrystalline semiconductor region 133a, leading to an increase in a leakage current upon application of gate negative bias.

It is desirable to provide a semiconductor device, a display, and a method of manufacturing the semiconductor device that are capable of suppressing an increase in a leakage current.

According to an embodiment of the technology, there is provided a semiconductor device, including: a gate electrode layer; a gate insulating film provided on the gate electrode layer; a semiconductor layer provided, in opposition to the gate electrode layer, on the gate insulating film; and a source-drain electrode layer provided on the semiconductor layer and on the gate insulating film. A face, in opposition to the gate insulating film, of the semiconductor layer is located above a face of a section, located on the gate insulating film, of the source-drain electrode layer.

According to an embodiment of the technology, there is provided a display provided with a semiconductor device, the semiconductor device including: a gate electrode layer; a gate insulating film provided on the gate electrode layer; a semiconductor layer provided, in opposition to the gate electrode layer, on the gate insulating film; and a source-drain electrode layer provided on the semiconductor layer and on the gate insulating film. A face, in opposition to the gate insulating film, of the semiconductor layer is located above a face of a section, located on the gate insulating film, of the source-drain electrode layer.

According to an embodiment of the technology, there is provided a method of manufacturing a semiconductor device, the method including: forming a gate insulating film on a gate electrode layer; forming, in opposition to the gate electrode layer, a semiconductor layer on the gate insulating film; and forming a source-drain electrode layer on the semiconductor layer and on the gate insulating film. A face, in opposition to the gate insulating film, of the semiconductor layer is located above a face of a section, located on the gate insulating film, of the source-drain electrode layer.

According to the semiconductor device, the display, and the method of manufacturing the semiconductor device of the respective embodiments described above, it is possible to suppress a decrease in characteristics of the semiconductor device.

It is to be understood that both the foregoing general description and the following detailed description are exemplary, and are intended to provide further explanation of the technology as claimed.

### BRIEF DESCRIPTION OF DRAWINGS

FIG. 1A illustrates an example of a configuration of an organic EL display, and FIG. 1B illustrates an example of a circuit configuration included in the organic EL display.

FIG. 2 is a plan view of a thin-film transistor according to a first embodiment of the technology.

FIG. 3 is a cross-sectional view of the thin-film transistor according to the first embodiment.

FIG. 4A and FIG. 4B are illustrations for describing a method of manufacturing the thin-film transistor according to the first embodiment.

FIG. 5A and FIG. 5B are further illustrations for describing the method of manufacturing the thin-film transistor according to the first embodiment.

FIG. 6 is a cross-sectional view of a thin-film transistor according to a second embodiment of the technology.

FIG. 7A and FIG. 7B are illustrations for describing a method of manufacturing the thin-film transistor according to the second embodiment.

FIG. 8 is a cross-sectional view of a thin-film transistor according to a third embodiment of the technology.

FIG. 9 is a plan view of a thin-film transistor according to a fourth embodiment of the technology.

FIG. 10 is a cross-sectional view of the thin-film transistor according to the fourth embodiment.

FIG. 11 is a plan view of a thin-film transistor according to a fifth embodiment of the technology.

FIG. 12 is a cross-sectional view of the thin-film transistor according to the fifth embodiment.

FIG. 13 is a plan view of a thin-film transistor according to a sixth embodiment of the technology.

FIG. 14 is a cross-sectional view of the thin-film transistor according to the sixth embodiment.

FIG. 15A and FIG. 15B are illustrations for describing a method of manufacturing the thin-film transistor according to the sixth embodiment.

FIG. 16 is a further illustration for describing the method of manufacturing the thin-film transistor according to the sixth embodiment.

### DESCRIPTION OF EMBODIMENTS

In the following, some embodiments of the technology will be described in detail with reference to the accompanying drawings.

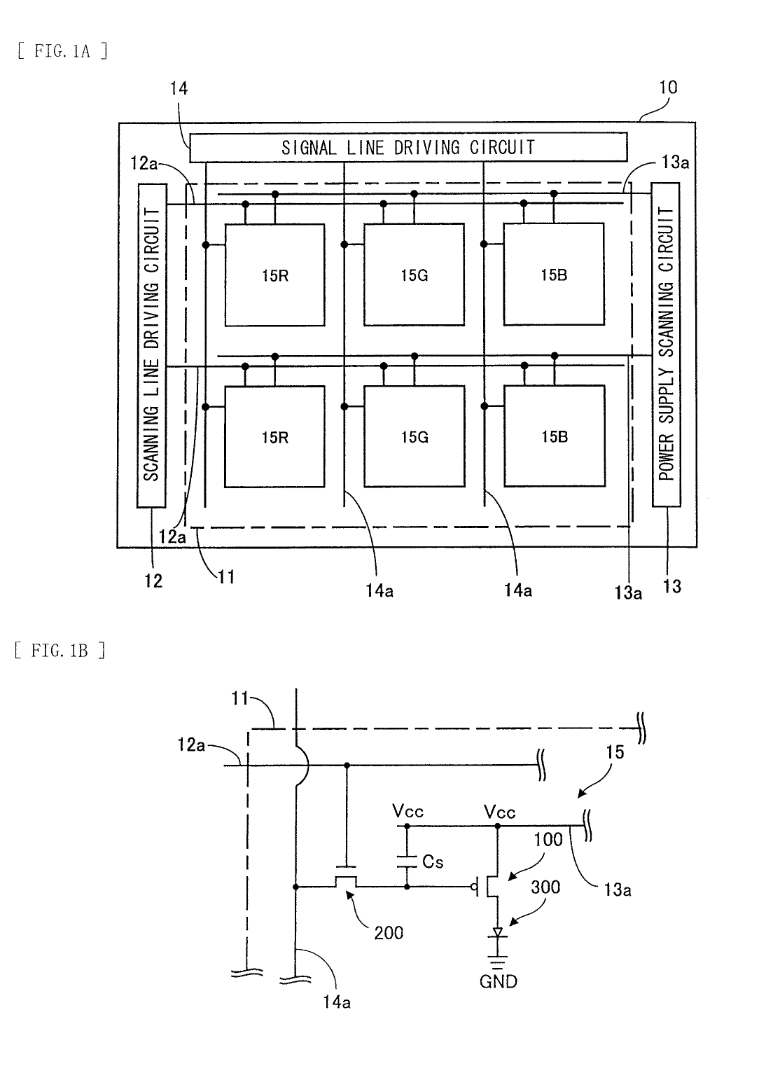

A description is given here of an example where a flat panel display may be an organic EL display. First, a configuration, etc., of the organic EL display is described below with reference to FIG. 1A and FIG. 1B.

FIG. 1A illustrates an exemplary configuration of the organic EL display, and FIG. 1B illustrates an exemplary circuit configuration included in the organic EL display.

The organic EL display, which may be of an active matrix type here, is a display that controls a current flowing through an organic EL device which is a current-driven electro-optic device. The organic EL display controls the current with use of an active device provided in the same pixel as the corresponding organic EL device, such as an insulated-gate field-effect transistor. Typically, a thin-film transistor (TFT) is used for the insulated-gate field-effect transistor.

Such organic EL display 10 may include a display region 11, a scanning line driving circuit 12, a power supply scanning circuit 13, and a signal line driving circuit 14, as illustrated in FIG. 1. The scanning line driving circuit 12, the power supply scanning circuit 13, and the signal line driving circuit 14 each serve as a driver used for image displaying.

The display region 11 include a pixel 15R, a pixel 15G, and a pixel 15B that may be arranged in matrix having “m” rows and “n” columns, for example. The pixel 15R, the pixel 15G, and the pixel 15B may emit red (R) light, green (B) light, and blue (B) light, respectively. In such array of pixels 15, a scanning line 12a and a power supply line 13a are arrayed for each row in a row direction (in an array direction of pixels belonging to pixel rows), and a signal line 14a is arrayed for each column in a column direction (in an array direction of pixels belonging to pixel columns).

The scanning line driving circuit 12 may include, for example, a shift register circuit that shifts or transfers in sequence a start pulse in synchronization with a clock pulse. In writing an image signal to each of the pixels 15 in the display region 11, the scanning line driving circuit 12 sequentially supplies the scanning lines 12a with a write scanning signal to thereby perform scanning of the respective pixels 15 in the display region 11 in order on a row-by-row basis (i.e., performs a line-sequential scanning).

The power supply scanning circuit 13 may include, for example, a shift register circuit that shifts in sequence a start pulse in synchronization with a clock pulse. The power supply scanning circuit 13 supplies the power supply lines 13a with a power supply potential (Vcc) in synchronization with the line-sequential scanning performed by the scanning line driving circuit 12.

The signal line driving circuit 14 selectively outputs a signal voltage and a reference potential. The signal voltage is supplied from an unillustrated signal supply source, and serves as an image signal corresponding to luminance information (hereinafter may be simply referred to as “signal voltage”). The signal voltage or the reference potential output from the signal line driving circuit 14 is written through the signal lines 14a into each of the pixels 15 in the display region 11 on a row-by-row basis selected by the scanning performed by the scanning line driving circuit 12. In other words, the signal line driving circuit 14 performs the writing of the signal voltage sequentially on a row-by-row (a line-by-line) basis.

The pixel 15 may include a circuit configuration illustrated in FIG. 1B, for example. The pixel 15 includes an organic EL device 300, and a driving circuit that causes a current to flow through the organic EL device 300 to thereby drive the corresponding organic EL device 300.

The organic EL device 300 serves as a light-emitting section, and is a current-driven electro-optic device whose emission luminance varies depending on a current value supplied thereto. The organic EL device 300 is connected in series with a later-described TFT 100 between the power supply line 13a and ground (GND).

The driving circuit that drives the organic EL device 300 includes the TFT 100, a TFT 200, and a capacitor Cs. The TFT 100 drives the organic EL device 300, and the TFT 200 performs writing. Each of the TFT 100 and the TFT 200 may be an N-channel TFT. It is to be noted, however, that a combination of conductivity types for the TFT 100 and the TFT 200 described here is illustrative and not limited to the foregoing combination.

The TFT 100 has a first end (a source electrode or a drain electrode) connected to an anode electrode of the organic EL device 300, and a second end (the drain electrode or the source electrode) connected to the power supply line 13a.

The TFT 200 has a first end (a source electrode or a drain electrode) connected to the signal line 14a, and a second end (the drain electrode or the source electrode) connected to a gate electrode of the TFT 100. A gate electrode of the TFT 200 is connected to the signal line 12a.

In the TFT 100 and the TFT 200, the “first electrode” refers to a metal wiring that is electrically connected to a source region or a drain region, and the “second electrode” refers to a metal wiring that is electrically connected to the drain region or the source region. The first electrode may serve as the source electrode or as the drain electrode, and the second electrode may serve as the drain electrode or as the source electrode, depending upon a relationship of potential between the first electrode and the second electrode.

The capacitor Cs has a first electrode connected to the gate electrode of the TFT 100, and a second electrode connected to the second electrode of the TFT 200.

In the following, various example embodiments of the TFT 100, included in the organic EL display 10 and serves to drive the organic EL device 300 as described above, are described.

### First Embodiment

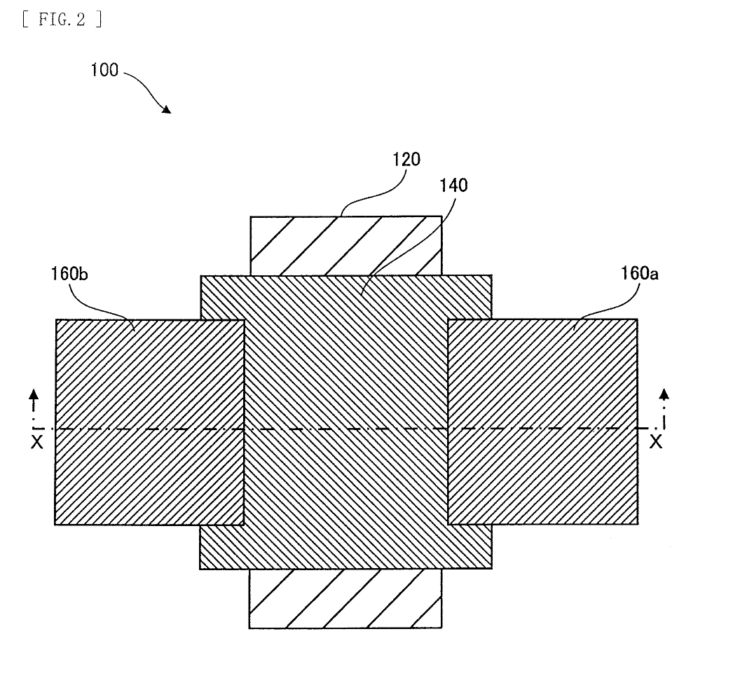

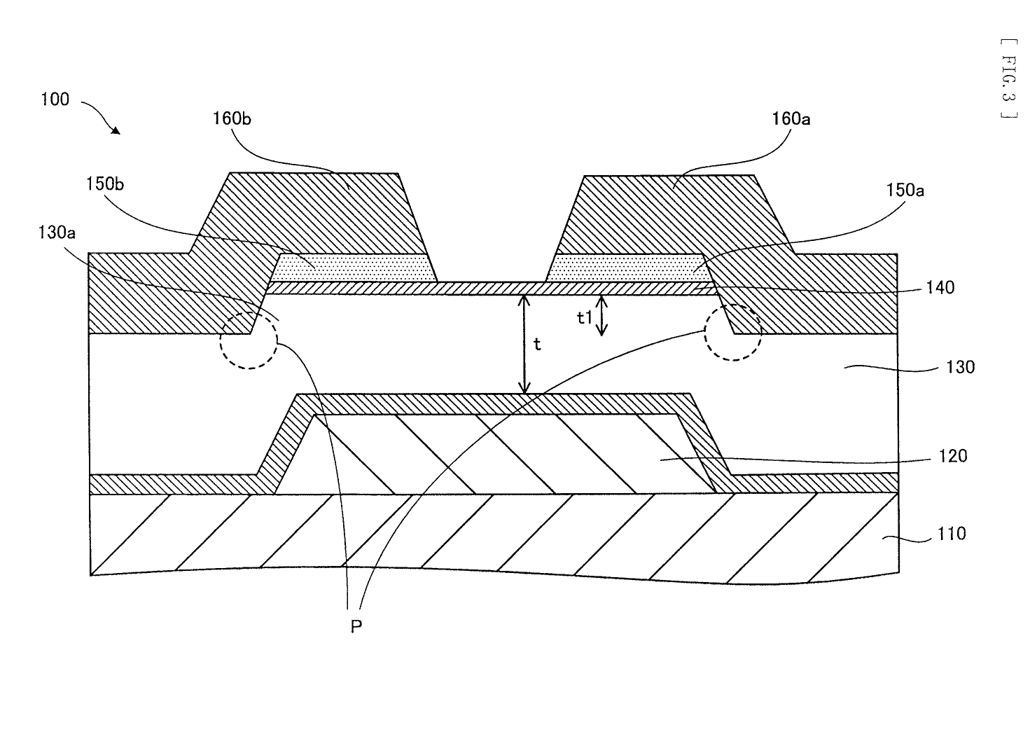

A description is given of a first embodiment with reference to FIG. 2 and FIG. 3. The first embodiment is described referring to an exemplary case where the TFT 100 is manufactured using a back-channel etching process.

FIG. 2 is a plan view of the thin-film transistor according to the first embodiment, and FIG. 3 is a cross-sectional view of the thin-film transistor according to the first embodiment.

Note that FIG. 2 illustrates a relationship of arrangement in plan view among only a gate electrode layer 120, a semiconductor layer 140, and source-drain electrode layers 160a and 160b in the TFT 100. FIG. 3 illustrates, in an enlarged fashion, a principal part of a cross-section taken along a dashed line X-X in FIG. 2.

Referring to FIG. 3, the TFT 100 includes the gate electrode layer 120 which may be formed on a substrate 110 through an unillustrated underlayer (a type of insulating film). For example, the substrate 110 may be made of a glass, and the gate electrode layer 120 may be made of a metal having a high-melting point such as molybdenum. The TFT 100 also includes a gate insulating film 130, the semiconductor layer 140, source-drain semiconductor layers 150a and 150b, and the source-drain electrode layers 160a and 160b which are stacked in order on the gate electrode layer 120.

The gate electrode layer 120 has a width (in a lateral direction of the drawing) configured to be narrower than a width of the later-described semiconductor layer 140 as illustrated in FIG. 2 and FIG. 3.

The gate insulating film 130 is so formed on the substrate 110 and the gate electrode layer 120 as to cover a surface section of the gate electrode layer 120. Also, the gate insulating film 130 may be formed with a raised section 130a at an upper section thereof in FIG. 3. The raised section 130a may be configured by a stepped section. Out of a section on the source-side (hereinafter simply referred to as a “source-side section”) and a section on the drain side (hereinafter simply referred to as a “drain-side section”) of the gate insulating film 130, the stepped section is dug-down and formed at least at the drain-side section. The source-side section and the drain-side section are adjacent to a region of the gate insulating film 130 in which the later-described semiconductor layer 140 is formed. FIG. 3 illustrates an example in which both of the source-side section and the drain-side section that are adjacent to the region of the gate insulating film 130 are dug-down. The raised section 130a may have a taper angle that is less than 90 degrees. The gate insulating film 130 may be formed by a single layer of silicon nitride or silicon oxide, for example. Alternatively, the gate insulating film 130 may be a multilayer film. In an example where the gate insulating film 130 is a multilayer film, a bottom layer may be formed of silicon nitride, and a top layer may be formed of silicon oxide.

A height “t1” of the raised section 130a of the gate insulating film 130 is preferably in a range from about 3 nm to about 200 nm both inclusive (or in a range from about 1% to about 70% both inclusive), and is more preferably in a range from about 10 nm to about 60 nm both inclusive (or in a range from about 3% to about 20% both inclusive), where a thickness “t” of the gate insulating film 130 from a top surface of the gate electrode layer 120 up to a bottom surface of the later-described semiconductor layer 140 is 300 nm. A result of simulation, according to the height t1, on a change in electric field intensity with respect to the semiconductor layer 140 revealed that the electric field intensity decreased sharply when the height t1 was up to about 10 nm. The electric field intensity decreased with further increase in the height t1, although the decreased electric field intensity showed no change when the height t1 exceeded about 60 nm. It is thus more preferable that the height t1 be in the foregoing range in consideration of the result of simulation and an accuracy of etching to be actually performed.

The semiconductor layer 140 may be formed on the raised section 130a of the gate insulating film 130, and functions as a channel region. The semiconductor layer 140 may be made of amorphous silicon or microcrystalline silicon. The semiconductor layer 140 may have a film thickness of about ten-odd nm in an example where the semiconductor layer 140 is made of microcrystalline silicon. The semiconductor layer 140 may include an organic semiconductor material. Examples of the organic semiconductor material applicable to the semiconductor layer 140 may include pentacene, naphthacene, hexacene, heptacene, pyrene, chrysene, perylene, coronene, rubrene, polythiophene, polyacene, polyphenylene vinylene, polypyrrole, porphyrin, carbon nanotube, fullerene, metal phthalocyanine, and their derivatives. Alternatively, the semiconductor layer 140 may include an oxide semiconductor. The oxide semiconductor applicable to the semiconductor layer 140 may be a compound that contains oxygen and an element including indium, gallium, zinc, and tin, for example. More specifically, an amorphous oxide semiconductor may be an indium gallium zinc oxide, for example. Examples of a crystalline oxide semiconductor may include a zinc oxide, an indium zinc oxide, an indium gallium oxide, an indium tin oxide, an indium tin zinc oxide, and indium oxide. Those that are partially crystallized and have higher mobility among the materials given as the examples of the amorphous oxide semiconductor are further advantageous when applied to an embodiment of the technology. Also, those that have superior mobility among the materials given as the examples of the crystalline oxide semiconductor are applicable as amorphous oxide semiconductor to an embodiment of the technology and may achieve further effect.

The source-drain semiconductor layers 150a and 150b are each a semiconductor layer provided on the semiconductor layer 140 and to which a high concentration of N-type impurity or P-type impurity is added. Each of the source-drain semiconductor layers 150a and 150b is formed as a layer different from the semiconductor layer 140, and may have a thickness of about ten-odd nm.

The source-drain electrode layers 160a and 160b are formed on the source-drain semiconductor layers 150a and 150b, respectively, and on the gate insulating film 130. Such formation of the source-drain electrode layers 160a and 160b allows a face, in opposition to the gate insulating film 130, of the semiconductor layer 140 to be located above a face of a section, located on the gate insulating film 130, of each of the source-drain electrode layers 160a and 160b. The source-drain electrode layers 160a and 160b formed as described above are so disposed with respect to the semiconductor layer 140 as to be overlapped in part with respective sides of the semiconductor layer 140 as illustrated in FIG. 2.

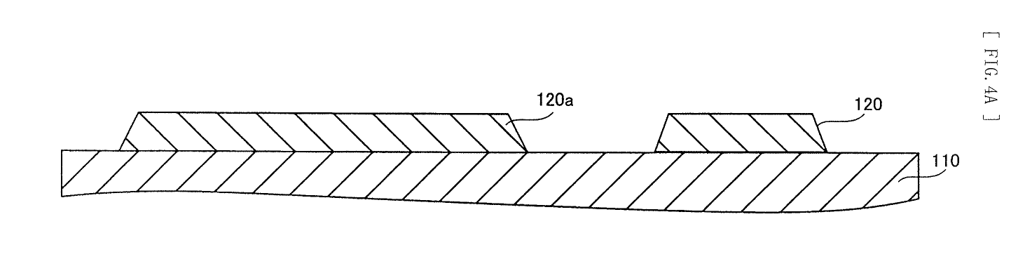

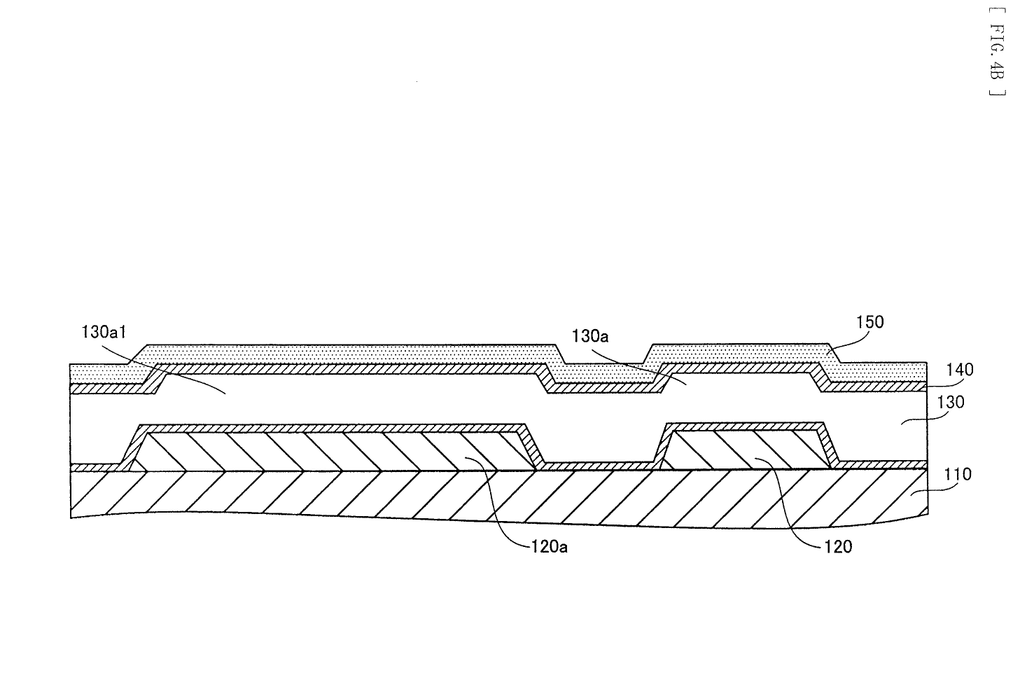

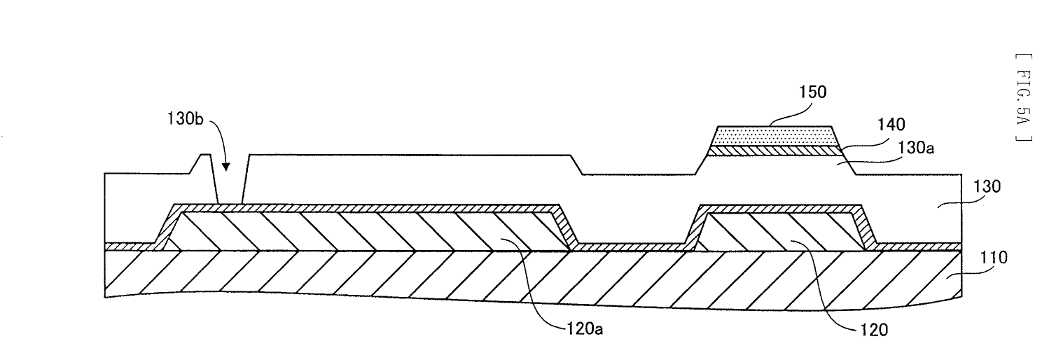

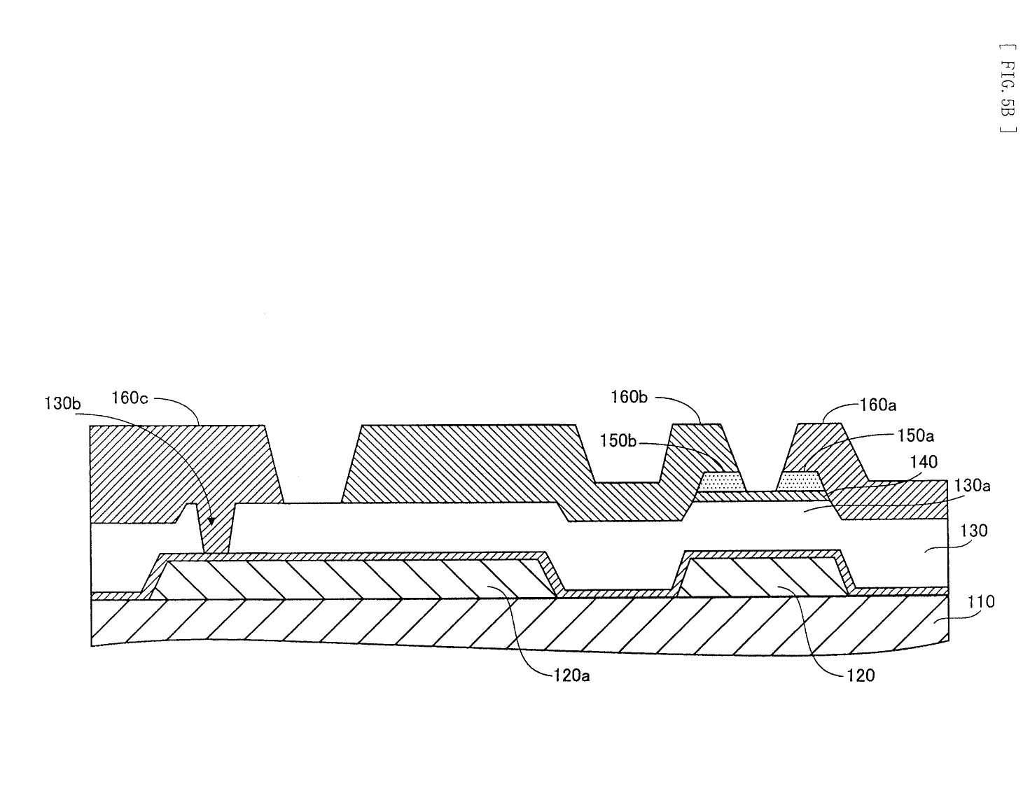

Next, a description is given with reference to FIGS. 4A, 4B, 5A, and 5B of a method of manufacturing the TFT 100 having a multilayer structure described above.

FIG. 4A to FIG. 5B are illustrations for describing a method of manufacturing the thin-film transistor according to the first embodiment. It is to be noted that, for example, the capacitor Cs located near the TFT 100 is also illustrated together with the TFT 100 in FIG. 4A to FIG. 5B.

First, a film of a metal material having conductivity, which may be molybdenum, for example, is formed on an insulative face of the substrate 110 which may be made of a glass, and the metal material film is processed to form the patterned gate electrode layer 120. Also, a gate metal layer 120a, which eventually serve as an electrode of the capacitor Cs, a backing layer of an unillustrated wiring, or the like, may be formed together in a region near the gate electrode layer 120 in forming the gate electrode layer 120 (FIG. 4A).

Then, the gate insulating film 130 is so formed on the substrate 110 as to cover the gate electrode layer 120 and the gate metal layer 120a, using a silicon oxide or a silicon nitride, for example. Further, the stepped sections may be dug-down and formed at regions, of the gate insulating film 130, corresponding to respective upper sections of the gate electrode layer 120 and the gate metal layer 120a to form the raised section 130a and a raised section 130a1. The semiconductor layer 140 and a source-drain semiconductor layer 150 may be formed in order on the gate insulating film 130 that is formed with the raised sections 130a and 130a1 (FIG. 4B).

Then, while leaving the semiconductor layer 140 and the source-drain semiconductor layer 150 that are located on the raised section 130a of the gate insulating film 130, the remaining other semiconductor layer 140 and the source-drain semiconductor layer 150 are removed using an etching process. This allows the semiconductor layer 140 to be formed in a self-aligning manner at a lower part of the source-drain semiconductor layer 150. Thereafter, an unillustrated resist having an opening at a predetermined location is formed on an upper surface of the gate insulating film 130 exposed after the removing, following which the gate insulating film 130 is etched to form a contact hole 130b (FIG. 5A).

Then, a source-drain electrode layer is so formed on the gate insulating film 130 as to cover the semiconductor layer 140 and the source-drain semiconductor layer 150, following which the layers are sequentially etched to form a desired pattern. This allows the source-drain semiconductor layer 150a and the source-drain electrode layer 160a to be formed separately from the source-drain semiconductor layer 150b and the source-drain electrode layer 160b, respectively, at an upper part of a channel-forming region. Also, in other region, a wiring layer 160c connected through the contact hole 130b to the gate metal layer 120a as a lower layer is formed (FIG. 5B).

The foregoing processes form the TFT 100, the capacitor Cs, etc.

After forming the TFT 100, the capacitor Cs, etc., an interlayer insulating film, a light-emission layer made of an organic material, an electrode layer, and a protective film, etc., are formed on the source-drain electrode layers 160a and 160b and on the wiring layer 160c at respective predetermined locations to form the organic EL device 300, thereby completing the pixel 15 of the organic EL display 10.

According to the TFT 100 as described above, the raised section 130a may be formed at an upper part of the gate insulating film 130 located above the gate electrode layer 120, and the semiconductor layer 140 and the source-drain semiconductor layers 150a and 150b may be formed in order on that raised section 130a. This allows the face, in opposition to the gate insulating film 130, of the semiconductor layer 140 to be located higher than the face of the section, located on the gate insulating film 130, of each of the source-drain electrode layers 160a and 160b that are so formed on the gate insulating film 130 as to cover the semiconductor layer 140 and the source-drain semiconductor layers 150a and 150b. In other words, because the semiconductor layer 140 is separated away from the vicinity of a P region of the gate insulating film 130 as illustrated in FIG. 3 to be located above the vicinity of the P region, the semiconductor layer 140 is prevented from being influenced by a concentration of electric field generated in the vicinity of the P region, making it possible to suppress generation of carrier in the semiconductor layer 140. As a result, it is possible to suppress an increase in a leakage current upon application of gate negative bias, and thereby to suppress a decrease in characteristics of the TFT 100.

Note that the TFT 100 according to the first embodiment is applicable to a liquid crystal display or any other suitable display without limitation to the organic EL display 10.

### Second Embodiment

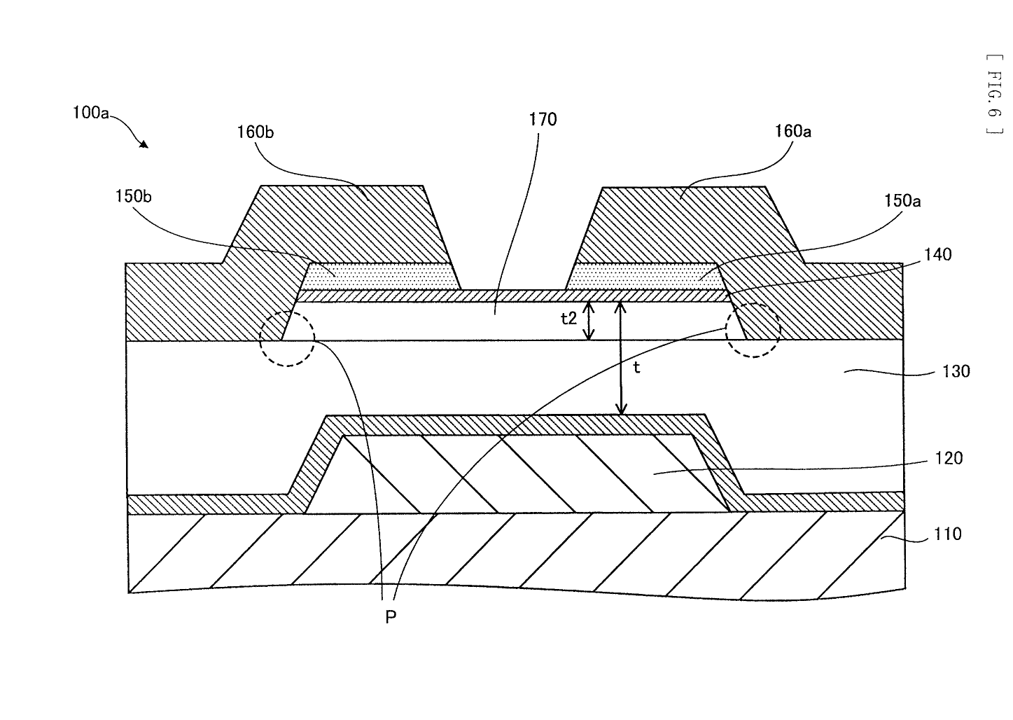

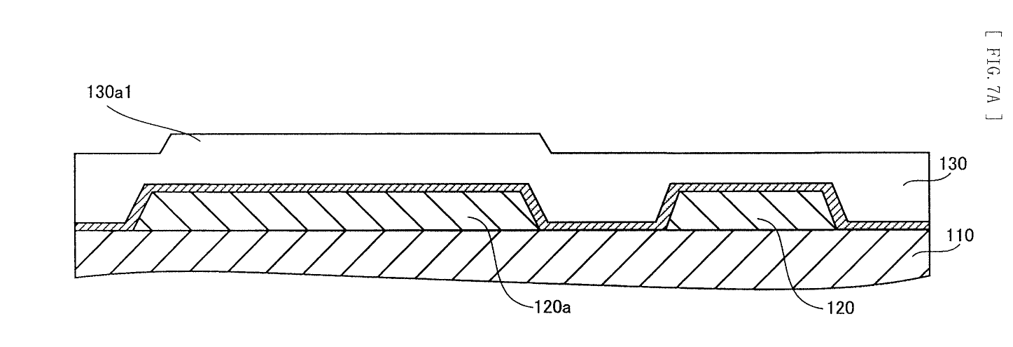

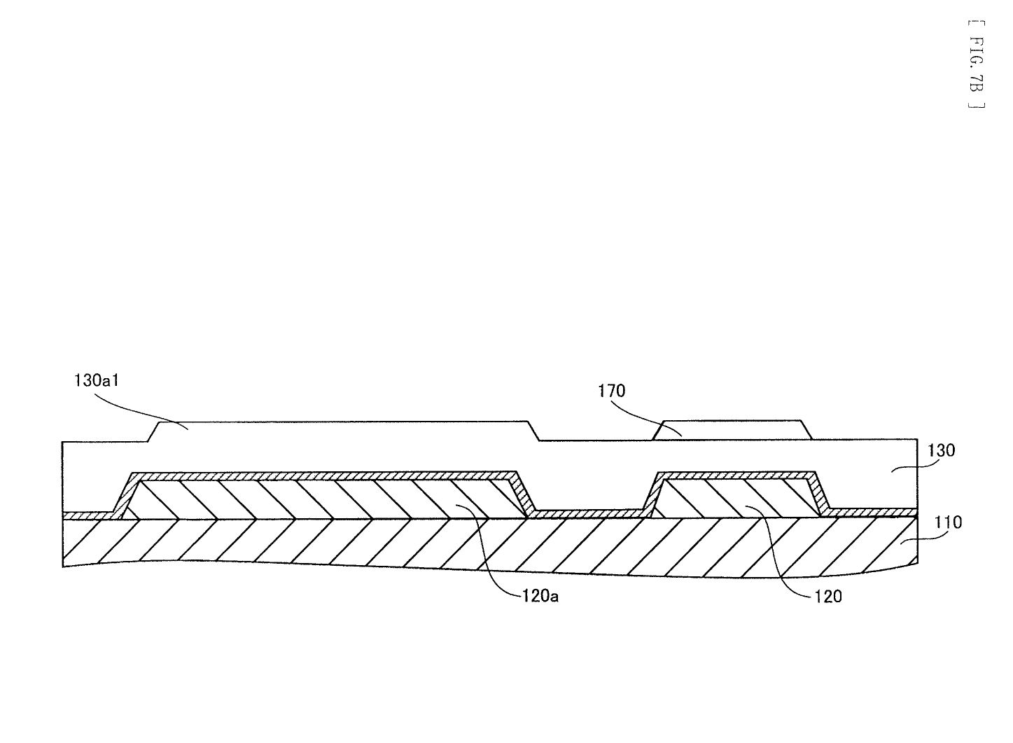

A description is given of a second embodiment with reference to FIG. 6, FIG. 7A, and FIG. 7B, where the TFT 100 according to the first embodiment is further formed with another insulating film on the gate insulating film 130.

FIG. 6 is a cross-sectional view of a thin-film transistor according to the second embodiment.

Note that a plan view of a TFT 100a is similar to the plan view of FIG. 2. FIG. 6 illustrates, in an enlarged fashion, a principal part of a cross-section taken along a dashed line X-X in the plan view of FIG. 2.

The TFT 100a has a configuration in which, instead of the raised section 130a of the gate insulating film 130 in the TFT 100 according to the first embodiment, a gate insulating film 170 is formed on the gate insulating film 130.

The gate insulating film 170 may be formed with the semiconductor layer 140 in a region in opposition to the gate electrode layer 120. Out of the source-side section and the drain-side section of the gate insulating film 170 that are adjacent to the region in which the semiconductor layer 140 is formed, at least the drain-side section of the gate insulating film 170 is removed. FIG. 6 illustrates an example in which both of the source-side section and the drain-side section that are adjacent to the region in which the semiconductor layer 140 is formed are removed. Also, the gate insulating film 170 may be made of a material having a higher dielectric constant than that of the gate insulating film 130. As in the first embodiment, a film thickness “t2” of the gate insulating film 170 is preferably in a range from about 3 nm to about 200 nm both inclusive (or in a range from about 1% to about 70% both inclusive), and is more preferably in a range from about 10 nm to about 60 nm both inclusive (or in a range from about 3% to about 20% both inclusive).

Next, a description is given with reference to FIG. 7A and FIG. 7B of a method of manufacturing the TFT 100a described above.

FIG. 7A and FIG. 7B are illustrations for describing a method of manufacturing the thin-film transistor according to the second embodiment.

After forming the gate electrode layer 120, etc., on the substrate 110 (FIG. 4A), the gate insulating film 130 is so formed on the substrate 110 as to cover the gate electrode layer 120, etc. Further, a section, corresponding to an upper part of the gate electrode layer 120, of the gate insulating film 130 is planarized, and the stepped sections may be dug-down and formed at sections, corresponding to an upper part of the gate metal layer 120a, of the gate insulating film 130 to form the raised section 130a1 (FIG. 7A).

Further, an insulating film which may have a higher dielectric constant than that of the gate insulating film 130 is formed on the gate insulating film 130, following which a section, corresponding to the upper part of the gate electrode layer 120, of the insulating film is patterned to have a predetermined shape, to thereby form the gate insulating film 170 (FIG. 7B).

The subsequent processes may be carried out in a similar fashion to those illustrated in FIG. 4B to FIG. 5B to form the TFT 100a (FIG. 6).

According to the TFT 100a as described above, the gate insulating film 170 may be formed at an upper part of the gate insulating film 130 located above the gate electrode layer 120, and the semiconductor layer 140 and the source-drain semiconductor layers 150a and 150b may be formed in order on that gate insulating film 170. This allows the face, in opposition to the gate insulating film 130, of the semiconductor layer 140 to be located higher than the face of the section, located on the gate insulating film 130, of each of the source-drain electrode layers 160a and 160b that are so formed on the gate insulating film 130 as to cover the semiconductor layer 140 and the source-drain semiconductor layers 150a and 150b. In other words, because the semiconductor layer 140 is separated away from the vicinity of a P region of the gate insulating film 130 as illustrated in FIG. 6 to be located above the vicinity of the P region, the semiconductor layer 140 is prevented from being influenced by a concentration of electric field generated in the vicinity of the P region, making it possible to suppress the generation of carrier in the semiconductor layer 140. Further, the gate insulating film 170 may have the dielectric constant higher than that of the gate insulating film 130, making it possible to suppress the electric field on the semiconductor layer 140. As a result, it is possible to suppress an increase in a leakage current upon application of gate negative bias, and thereby to suppress a decrease in characteristics of the TFT 100a.

Note that the TFT 100a according to the second embodiment is applicable to a liquid crystal display or any other suitable display without limitation to the organic EL display 10.

### Third Embodiment

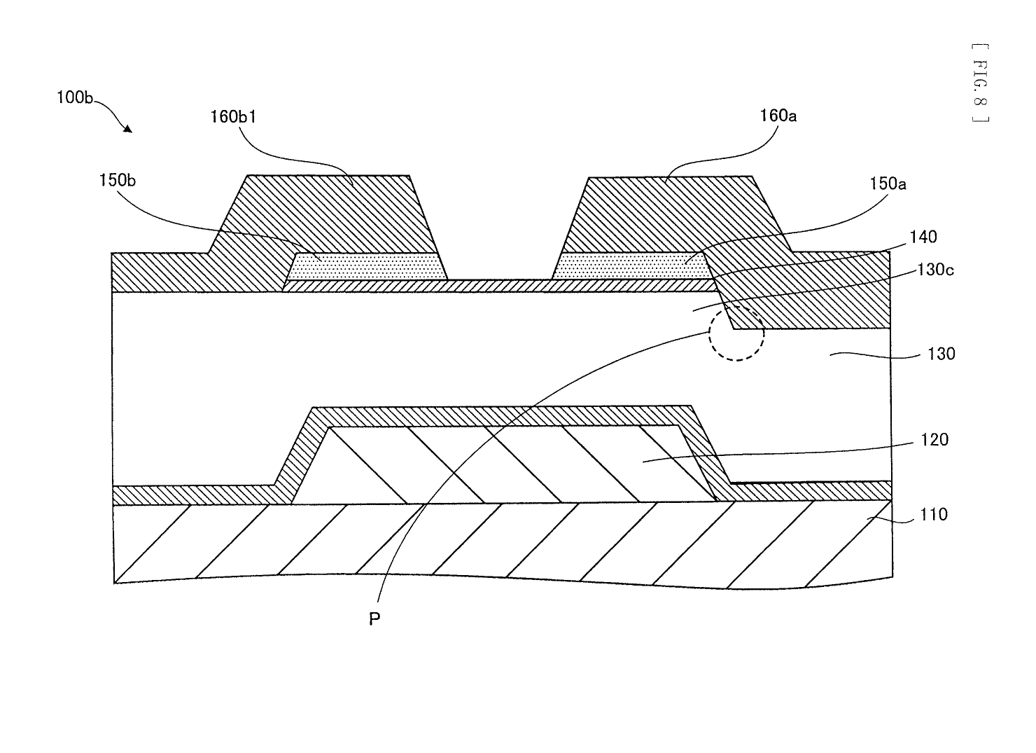

A description is given of a third embodiment with reference to FIG. 8, where the TFT 100 according to the first embodiment is formed with a raised section having the stepped section. The stepped section is provided on the gate insulating film 130 only on one side of the gate insulating film 130.

FIG. 8 is a cross-sectional view of a thin-film transistor according to the third embodiment.

Note that a plan view of a TFT 100b is similar to the plan view of FIG. 2. FIG. 8 illustrates, in an enlarged fashion, a principal part of a cross-section taken along a dashed line X-X in the plan view of FIG. 2.

In the organic EL display 10, a source of the TFT, which controls light emission of the organic EL display 10, is connected to an anode of the organic EL device 300, and a drain thereof is connected to a power source. Hence, a function of the source may not be exchanged with that of the drain and vice versa.

Therefore, in the TFT 100b used for the pixel 15 of the organic EL display 10, the stepped section may be dug-down and formed only on one side (for example, on the drain side) of the gate insulating film 130 in the TFT 100 of the first embodiment to form a raised section 130c. As in the first embodiment, a height of the raised section 130c of the gate insulating film 130 is preferably in a range from about 3 nm to about 200 nm both inclusive (or in a range from about 1% to about 70% both inclusive), and is more preferably in a range from about 10 nm to about 60 nm both inclusive (or in a range from about 3% to about 20% both inclusive).

The semiconductor layer 140, the source-drain semiconductor layers 150a and 150b, and the source-drain electrode layers 160a and 160b1 may be formed on an upper region of the raised section 130c of the gate insulating film 130.

According to the TFT 100b as described above, the stepped section may be dug-down and formed on the gate insulating film 130 only on one side of the gate insulating film 130 located above the gate electrode layer 120 to form the raised section 130c, and the semiconductor layer 140 and the source-drain semiconductor layers 150a and 150b may be formed in order on that raised section 130c. This allows the face, in opposition to the gate insulating film 130, of the semiconductor layer 140 to be located higher than the face of the section, located on the gate insulating film 130, of each of the source-drain electrode layers 160a and 160b1 that are so formed on the gate insulating film 130 as to cover the semiconductor layer 140 and the source-drain semiconductor layers 150a and 150b. In other words, because the semiconductor layer 140 is separated away from the vicinity of a P region of the gate insulating film 130 as illustrated in FIG. 8 to be located above the vicinity of the P region, the semiconductor layer 140 is prevented from being influenced by a concentration of electric field generated in the vicinity of the P region, making it possible to suppress the generation of carrier in the semiconductor layer 140. As a result, it is possible to suppress an increase in a leakage current upon application of gate negative bias, and thereby to suppress a decrease in characteristics of the TFT 100b.

Note that the TFT 100b according to the third embodiment is applicable to a liquid crystal display or any other suitable display without limitation to the organic EL display 10.

### Fourth Embodiment

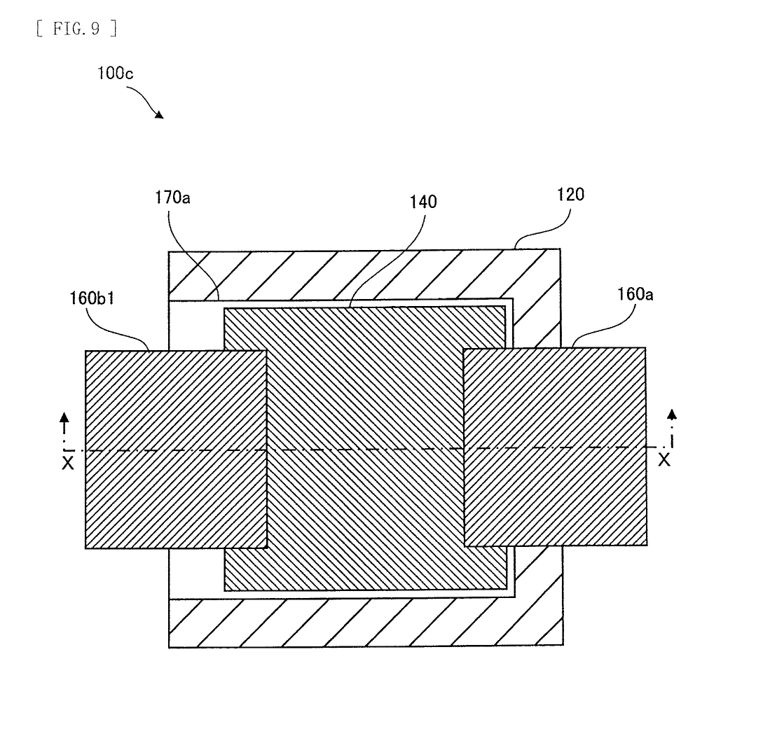

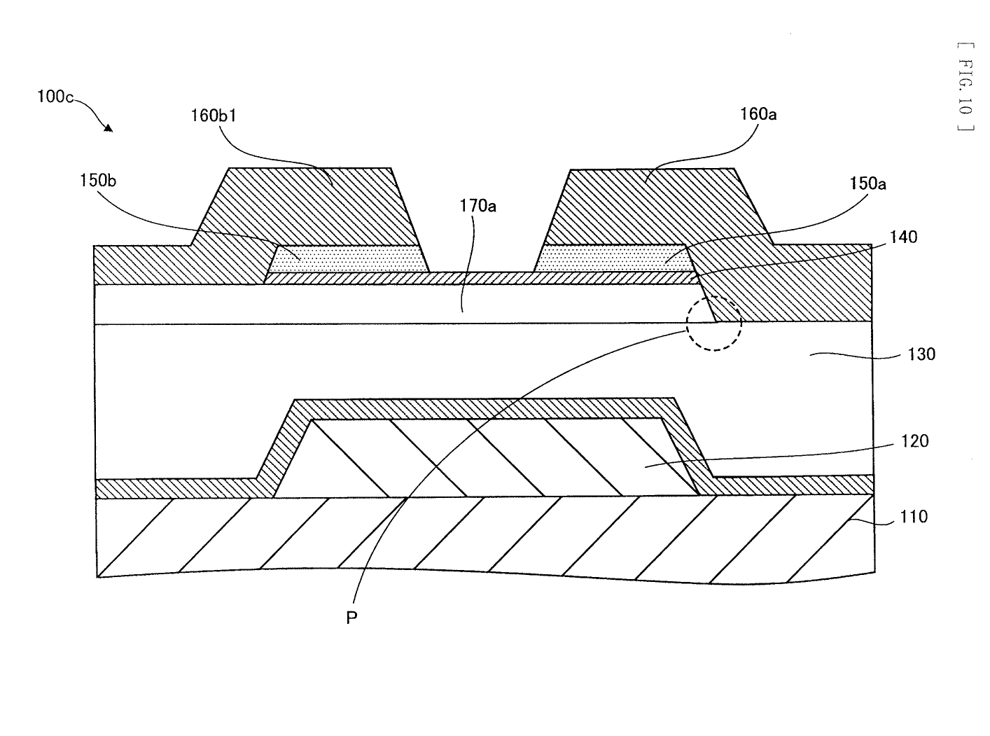

A description is given of a fourth embodiment with reference to FIG. 9 and FIG. 10, where the TFT 100b according to the third embodiment is further formed with another insulating film on the gate insulating film 130.

FIG. 9 is a plan view of a thin-film transistor according to the fourth embodiment, and FIG. 10 is a cross-sectional view of the thin-film transistor according to the fourth embodiment.

Note that FIG. 9 illustrates a relationship of arrangement in plan view among only the gate electrode layer 120, a gate insulating film 170a, the semiconductor layer 140, and the source-drain electrode layers 160a and 160b1 in the TFT 100c. FIG. 10 illustrates, in an enlarged fashion, a principal part of a cross-section taken along a dashed line X-X in FIG. 9.

The TFT 100c has a configuration in which, instead of the raised section 130c of the gate insulating film 130 in the TFT 100b according to the third embodiment, the gate insulating film 170a which may have a higher dielectric constant than that of the gate insulating film 130 is formed on the gate insulating film 130 as illustrated in FIG. 10. Also, as illustrated in FIG. 9, the gate insulating film 170a may be formed with the semiconductor layer 140 in a region in opposition to the gate electrode layer 120, and the drain-side section, of the gate insulating film 170, adjacent to the region in which the semiconductor layer 140 is formed is removed. The gate insulating film 170a may be made of a material having a higher dielectric constant than that of the gate insulating film 130. As in the first embodiment, a film thickness of the gate insulating film 170a is preferably in a range from about 3 nm to about 200 nm both inclusive (or in a range from about 1% to about 70% both inclusive), and is more preferably in a range from about 10 nm to about 60 nm both inclusive (or in a range from about 3% to about 20% both inclusive).

According to the TFT 100c as described above, the gate insulating film 170a may be formed at an upper part of the gate insulating film 130 located above the gate electrode layer 120, and the semiconductor layer 140 and the source-drain semiconductor layers 150a and 150b may be formed in order on that gate insulating film 170a. This allows the face, in opposition to the gate insulating film 130, of the semiconductor layer 140 to be located higher than the face of the section, located on the gate insulating film 130, of each of the source-drain electrode layers 160a and 160b1 that are so formed on the gate insulating film 130 as to cover the semiconductor layer 140 and the source-drain semiconductor layers 150a and 150b. In other words, because the semiconductor layer 140 is separated away from the vicinity of a P region of the gate insulating film 130 as illustrated in FIG. 10 to be located above the vicinity of the P region, the semiconductor layer 140 is prevented from being influenced by a concentration of electric field generated in the vicinity of the P region, making it possible to suppress the generation of carrier in the semiconductor layer 140. Further, the gate insulating film 170a may have the dielectric constant higher than that of the gate insulating film 130, making it possible to suppress the electric field on the semiconductor layer 140. As a result, it is possible to suppress an increase in a leakage current upon application of gate negative bias, and thereby to suppress a decrease in characteristics of the TFT 100c.

Note that the TFT 100c according to the fourth embodiment is applicable to a liquid crystal display or any other suitable display without limitation to the organic EL display 10.

### Fifth Embodiment

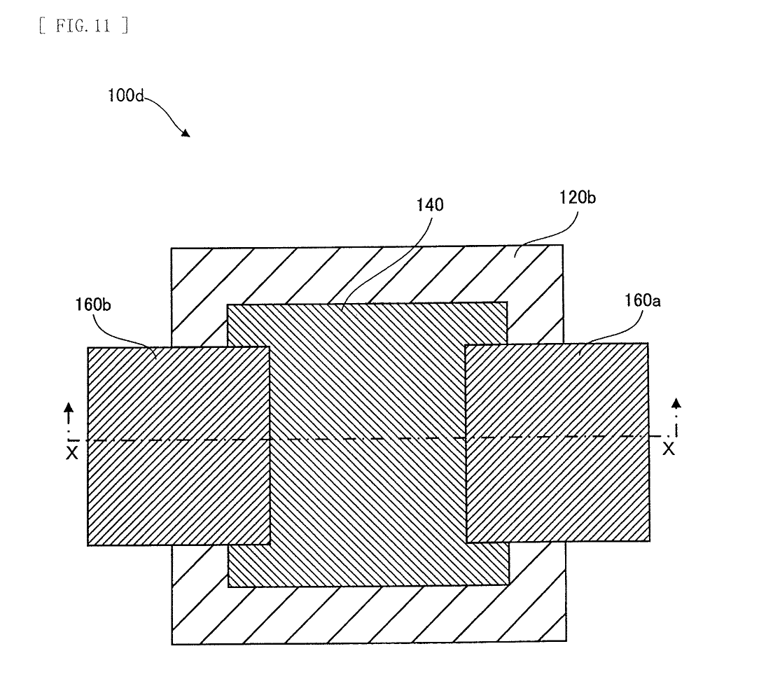

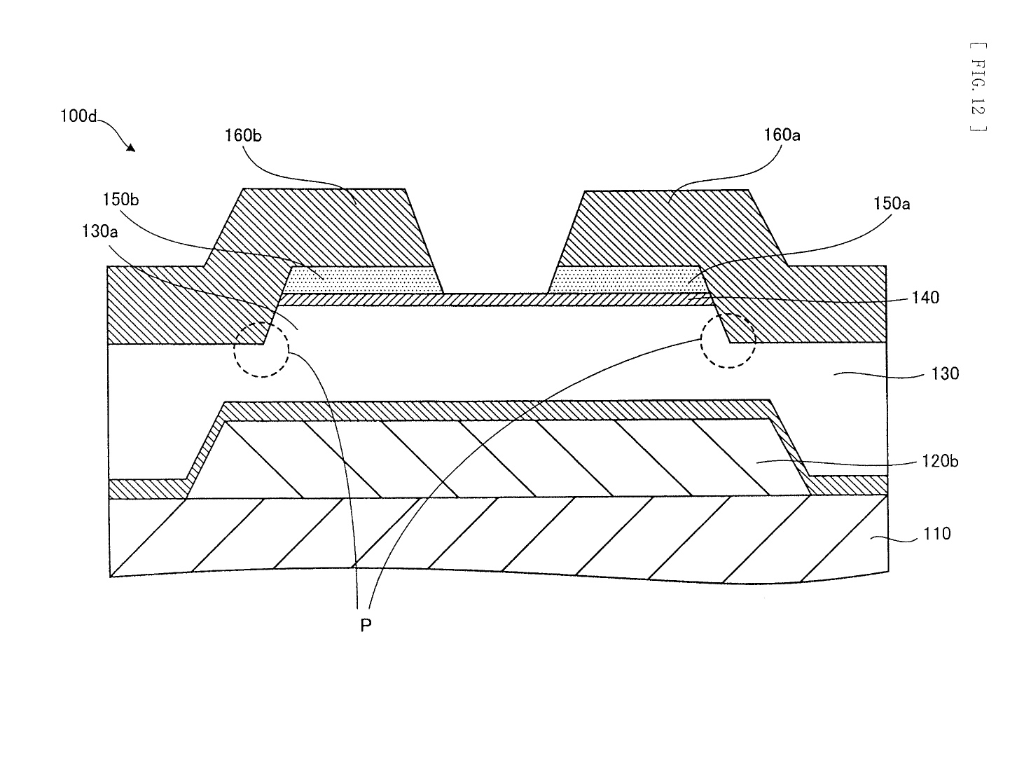

A description is given of a fifth embodiment with reference to FIG. 11 and FIG. 12, where the gate electrode layer is wider than the semiconductor layer 140 in plan view in the TFT 100 according to the first embodiment.

FIG. 11 is a plan view of a thin-film transistor according to the fifth embodiment, and FIG. 12 is a cross-sectional view of the thin-film transistor according to the fifth embodiment.

Note that FIG. 11 illustrates a relationship of arrangement in plan view among only the gate electrode layer 120b, the semiconductor layer 140, and the source-drain electrode layers 160a and 160b in the TFT 100d. FIG. 12 illustrates, in an enlarged fashion, a principal part of a cross-section taken along a dashed line X-X in FIG. 11.

As illustrated in FIG. 12, the gate electrode layer 120b of the TFT 100d may be so formed as to have a width (in a lateral direction in FIG. 12) wider than a width of the raised section 130a of the gate insulating film 130, and may be configured to be wider than the semiconductor layer 140 as illustrated in FIG. 11. The gate electrode layer 120b of the TFT 100d may be made of a material same as that of the gate electrode layer 120 of the first embodiment.

The TFT 100d as described above is applicable to a liquid crystal display or any other suitable display without limitation to the organic EL display 10. In the TFT 100d, the gate electrode layer 120 may be formed to be wider in plan view than the semiconductor layer 140. This makes it possible for the gate electrode layer 120b to block light that travels from the organic EL device 300 toward the semiconductor layer 140 as well as its associated reflected light, in an example where the TFT 100d is applied to the organic EL display 10. Also, this makes it possible for the gate electrode layer 120b to block illumination of light derived from, for example, a backlight or the like of the liquid crystal display as well as reflected light generated accordingly, in an example where the TFT 100d is applied to the liquid crystal display. As a result, it is possible to suppress generation of a photo-leakage current caused in the semiconductor layer 140 by the light derived from the organic EL device 300 or from the backlight of the liquid crystal display.

Also, with the exception of the gate electrode layer 120b, the TFT 100d has the similar configuration to that of the TFT 100 according to the first embodiment. Hence, the semiconductor layer 140 is separated away from the vicinity of a P region of the gate insulating film 130 as illustrated in FIG. 12 to be located above the vicinity of the P region. Thus, the semiconductor layer 140 is prevented from being influenced by a concentration of electric field generated in the vicinity of the P region, making it possible to suppress the generation of carrier in the semiconductor layer 140. As a result, it is possible to suppress an increase in a leakage current upon application of gate negative bias, and thereby to suppress a decrease in characteristics of the TFT 100d.

Therefore, the foregoing TFT 100d makes it possible to suppress the increase in the leakage current upon application of the gate negative bias and to suppress the generation of the photo-leakage current as well.

Note that the TFT 100d according to the fifth embodiment may have a configuration in which the gate insulating film 170 is provided instead of the raised section 130a, the stepped section is provided at an upper part of the gate insulating film 130 only on one side of the gate insulating film 130, or the gate insulating film 170a is provided instead of the raised section 130a, as in the second, the third, or the fourth embodiment.

### Sixth Embodiment

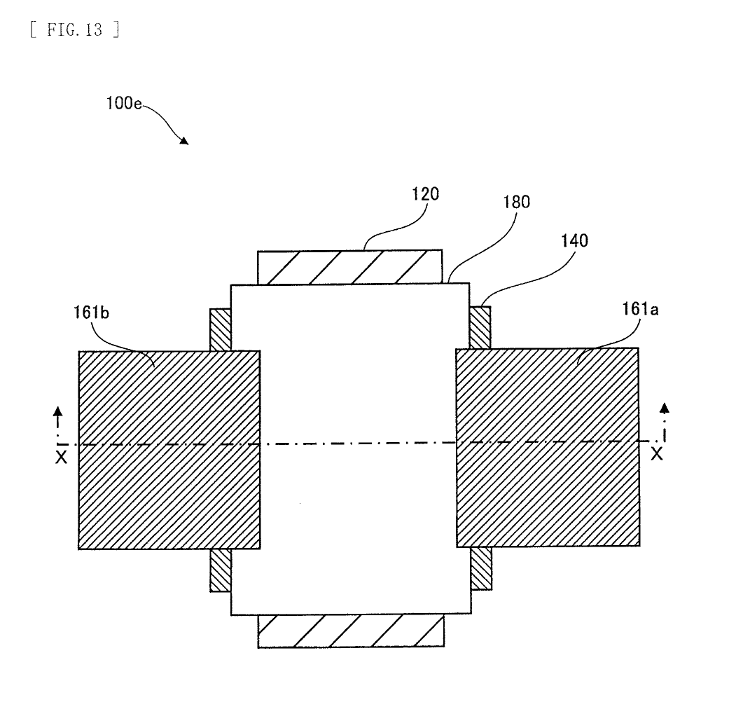

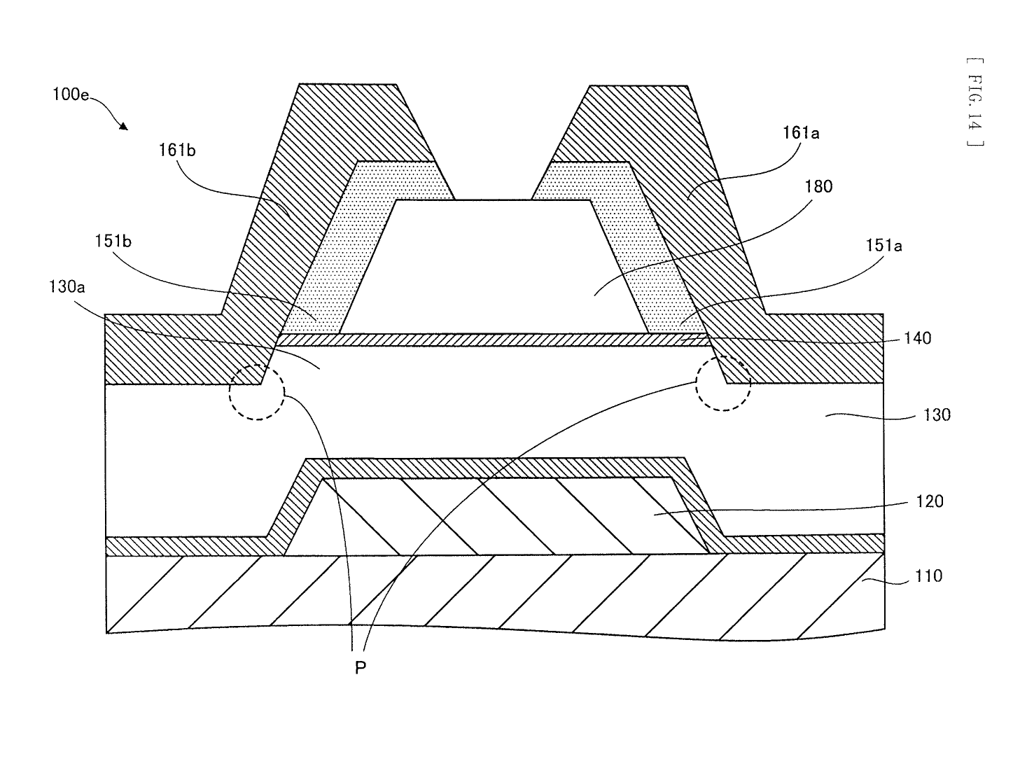

A description is given of a sixth embodiment with reference to FIG. 13 and FIG. 14. The sixth embodiment is described referring to an exemplary case where a TFT 100e is manufactured using an etching-stopper process.

FIG. 13 is a plan view of a thin-film transistor according to the sixth embodiment, and FIG. 14 is a cross-sectional view of the thin-film transistor according to the sixth embodiment.

Note that FIG. 13 illustrates a relationship of arrangement in plan view among only the gate electrode layer 120, the semiconductor layer 140, a channel protecting film 180, and source-drain electrode layers 161a and 161b in the TFT 100e. FIG. 14 illustrates, in an enlarged fashion, a principal part of a cross-section taken along a dashed line X-X in FIG. 13.

Referring to FIG. 14, the TFT 100e includes the gate electrode layer 120 which may be formed on the substrate 110 through an unillustrated underlayer (a type of insulating film). For example, the substrate 110 may be made of a glass, and the gate electrode layer 120 may be made of a metal having a high-melting point such as molybdenum. The TFT 100e also includes the gate insulating film 130, the semiconductor layer 140, source-drain semiconductor layers 151a and 151b, and the source-drain electrode layers 161a and 161b which are stacked in order on the gate electrode layer 120. Further, the TFT 100e may be formed with the channel protecting film 180 on the semiconductor layer 140.

The channel protecting film 180 may be formed of silicon nitride, for example. As illustrated in FIG. 13 and FIG. 14, the channel protecting film 180 may be disposed on the semiconductor layer 140, and may include an end face gently sloped to have a forward tapered shape. Providing the channel protecting film 180 on the semiconductor layer 140 as described above makes it possible to protect the semiconductor layer 140 from etching for processing upon manufacturing of the TFT 100e. Also, the channel protecting film 180 has a thickness for protection of the semiconductor layer 140 as described above, and also has a function of maintaining a stress balance with the source-drain electrode layers 161a and 161b as a whole.

The source-drain semiconductor layers 151a and 151b may be the same in material applied thereto as the source-drain semiconductor layers 150a and 150b described in the first embodiment to the fifth embodiment, respectively. Likewise, the source-drain electrode layers 161a and 161b may be the same in material applied thereto as the source-drain electrode layers 160a and 160b described in the first embodiment to the fifth embodiment, respectively.

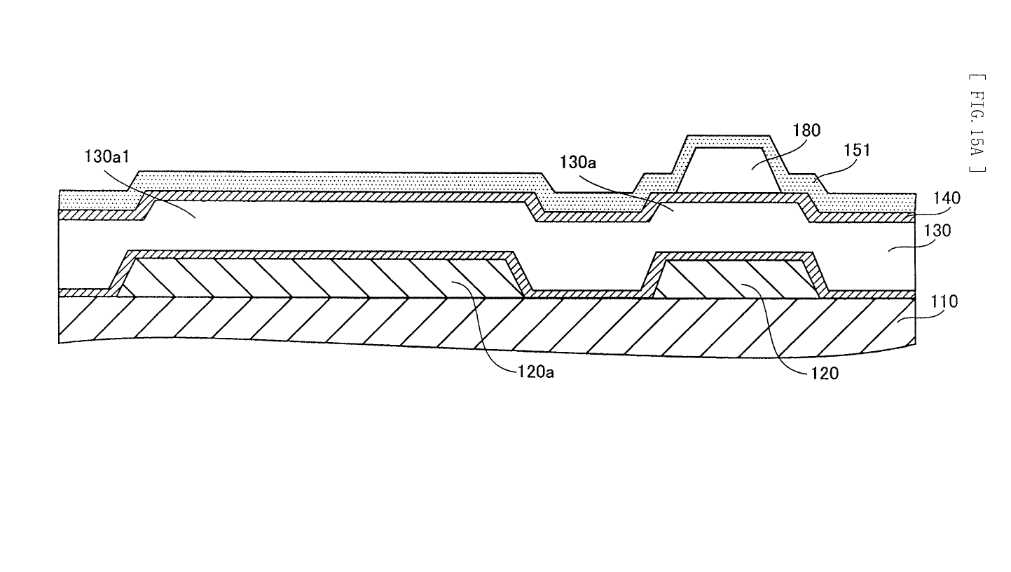

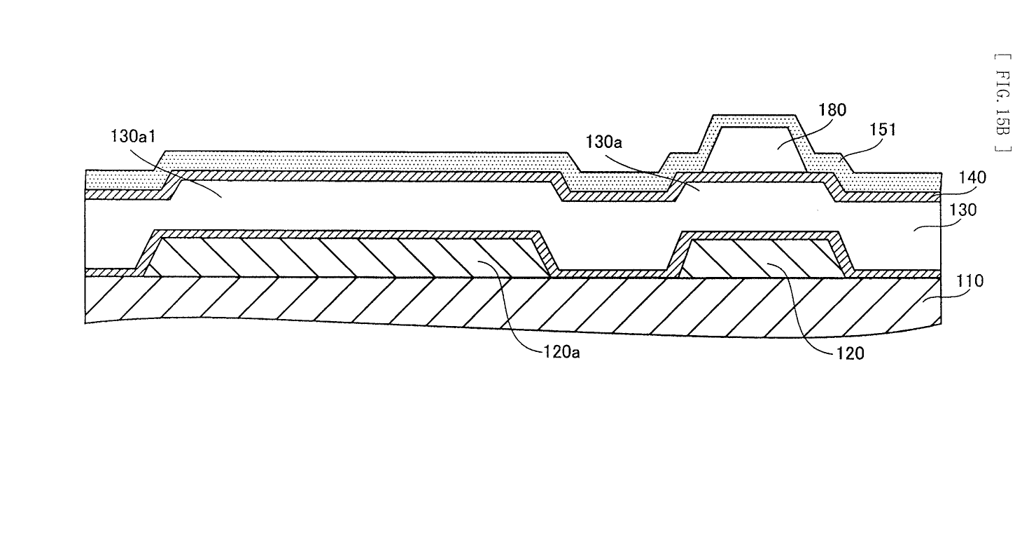

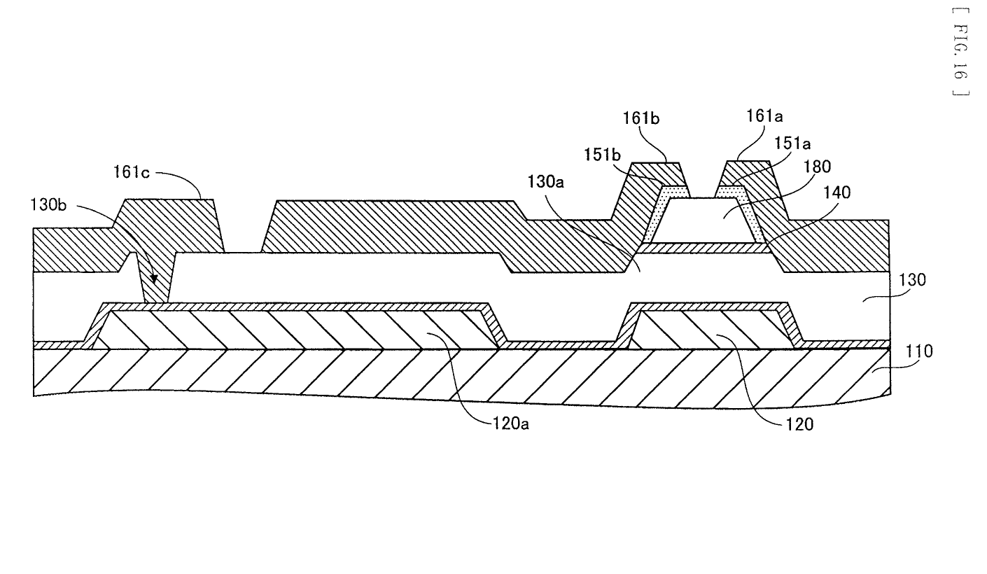

Next, a description is given with reference to FIGS. 15A, 15B and 16 of a method of manufacturing the TFT 100e having a multilayer structure described above.

FIG. 15A to FIG. 16 are illustrations for describing a method of manufacturing the thin-film transistor according to the sixth embodiment. It is to be noted that, for example, the capacitor Cs located near the TFT 100e is also illustrated together with the TFT 100e in FIG. 15A to FIG. 16.

First, as with the first embodiment, a film of a metal material having conductivity, which may be molybdenum for example, is formed on an insulative face of the substrate 110, and the metal material film is processed to form the gate electrode layer 120 and the gate metal layer 120a (FIG. 4A).

Then, as with the example illustrated in FIG. 4B, the gate insulating film 130 is so formed on the substrate 110 as to cover the gate electrode layer 120 and the gate metal layer 120a, and the raised sections 130a and 130a1 may be further formed on the gate insulating film 130. Moreover, the semiconductor layer 140 may be formed on the gate insulating film 130 that is formed with the raised sections 130a and 130a1.

A film, which may be made of a silicon nitride for example, is formed on the semiconductor layer 140 and is patterned to form the channel protecting film 180 at an upper part of the semiconductor layer 140. A source-drain semiconductor layer 151 may be formed on the semiconductor layer 140 and on the channel protecting film 180 (FIG. 15A).

The source-drain semiconductor layer 151 may be so patterned as to leave a section on the raised section 130a and to remove any unnecessary section. This allows the semiconductor layer 140 to be formed in a self-aligning manner at a lower part of the source-drain semiconductor layer 151 (FIG. 15B).

Then, a source-drain electrode layer is so formed on the gate insulating film 130 as to cover the semiconductor layer 140 and the source-drain semiconductor layer 151, following which the layers are sequentially etched to form a desired pattern. This allows the source-drain semiconductor layer 151a and the source-drain electrode layer 161a to be formed separately from the source-drain semiconductor layer 151b and the source-drain electrode layer 161b, respectively, at an upper part of a channel-forming region. Also, in other region, a wiring layer 161c connected through the contact hole 130b to the gate metal layer 120a as a lower layer is formed (FIG. 16).

The foregoing processes form the TFT 100e, the capacitor Cs, etc.

After forming the TFT 100e, the capacitor Cs, etc., an interlayer insulating film, a light-emission layer made of an organic material, an electrode layer, and a protective film, etc., are formed on the source-drain electrode layers 161a and 161b and on the wiring layer 161c at respective predetermined locations to form the organic EL device 300, thereby completing the pixel 15 of the organic EL display 10.

According to the TFT 100e as described above, the raised section 130a may be formed at an upper part of the gate insulating film 130 located above the gate electrode layer 120, and the semiconductor layer 140, the channel protecting film 180, and the source-drain semiconductor layers 151a and 151b may be formed in order on that raised section 130a. This allows the face, in opposition to the gate insulating film 130, of the semiconductor layer 140 to be located higher than the face of the section, located on the gate insulating film 130, of each of the source-drain electrode layers 161a and 161b that are so formed on the gate insulating film 130 as to cover the semiconductor layer 140, the channel protecting film 180, and the source-drain semiconductor layers 151a and 151b. In other words, because the semiconductor layer 140 is separated away from the vicinity of a P region of the gate insulating film 130 as illustrated in FIG. 14 to be located above the vicinity of the P region, the semiconductor layer 140 is prevented from being influenced by a concentration of electric field generated in the vicinity of the P region, making it possible to suppress the generation of carrier in the semiconductor layer 140. As a result, it is possible to suppress an increase in a leakage current upon application of gate negative bias, and thereby to suppress a decrease in characteristics of the TFT 100e.

Also, in the TFT 100e, the channel protecting film 180 may be formed on the semiconductor layer 140. This makes it possible to prevent the semiconductor layer 140 from being damaged due to processing, etching, and/or the like upon manufacturing of the TFT 100e, and to suppress a decrease in characteristics of the semiconductor device 100e.

Note that a configuration similar to that according to any of the second embodiment to the fifth embodiment may be applied to the TFT 100e according to the sixth embodiment. For example, the TFT 100e according to the sixth embodiment may have a configuration in which the gate insulating film 170 is provided instead of the raised section 130a, the stepped section is provided at an upper part of the gate insulating film 130 only on one side of the gate insulating film 130, or the gate insulating film 170a is provided instead of the raised section 130a. In particular, providing the gate electrode layer 120b that is wider in plan view than the semiconductor layer 140 instead of the gate electrode layer 120 makes it possible to block the light that travels from the organic EL device 300 of the organic EL display 10 toward the semiconductor layer 140, or the light derived from, for example, the backlight or the like of the liquid crystal display. As a result, it is possible to suppress the generation of a photo-leakage current caused in the semiconductor layer 140 by the light derived from the organic EL device 300 or from the backlight of the liquid crystal display.

Although the technology has been described in the foregoing by way of example with reference to the example embodiments, the technology is not limited thereto but may be modified in a wide variety of ways.

Furthermore, the technology encompasses any possible combination of some or all of the various embodiments described herein and incorporated herein.

It is possible to achieve at least the following configurations from the above-described example embodiments of the disclosure.

(1) A semiconductor device, including:

a gate electrode layer;

a gate insulating film provided on the gate electrode layer;

a semiconductor layer provided, in opposition to the gate electrode layer, on the gate insulating film; and

a source-drain electrode layer provided on the semiconductor layer and on the gate insulating film,

wherein a face, in opposition to the gate insulating film, of the semiconductor layer is located above a face of a section, located on the gate insulating film, of the source-drain electrode layer.

(2) The semiconductor device according to (1), further including a raised section where the semiconductor layer is provided, the raised section being provided in a region, in opposition to the gate electrode layer, on the gate insulating film.
(3) The semiconductor device according to (2), wherein the raised section includes a stepped section that is dug-down and provided at a drain-side section or at both of a source-side section and the drain-side section of the gate insulating film, the source-side section and the drain-side section being adjacent to the region, of the gate insulating film, in which the semiconductor layer is provided.
(4) The semiconductor device according to (1), further including an insulating film provided on the gate insulating film,

wherein the semiconductor layer is provided in a region, in opposition to the gate electrode layer, of the insulating film, and

a drain-side section or both of a source-side section and the drain-side section of the insulating film is removed, the source-side section and the drain-side section being adjacent to the region, of the insulating film, in which the semiconductor layer is provided.

(5) The semiconductor device according to (4), wherein the insulating film has a dielectric constant higher than a dielectric constant of the gate insulating film.
(6) The semiconductor device according to any one of (1) to (5), wherein the gate electrode layer has a size that covers, in plan view, the semiconductor layer.
(7) The semiconductor device according to any one of (1) to (6), further including a protecting film provided on the semiconductor layer, wherein the source-drain electrode layer is provided on the protecting film.
(8) The semiconductor device according to any one of (1) to (7), wherein the semiconductor layer includes an organic semiconductor.
(9) The semiconductor device according to any one of (1) to (7), wherein the semiconductor layer includes an oxide semiconductor.
(10) A display provided with a semiconductor device, the semiconductor device including:

a gate electrode layer;

a gate insulating film provided on the gate electrode layer;

a semiconductor layer provided, in opposition to the gate electrode layer, on the gate insulating film; and

a source-drain electrode layer provided on the semiconductor layer and on the gate insulating film,

wherein a face, in opposition to the gate insulating film, of the semiconductor layer is located above a face of a section, located on the gate insulating film, of the source-drain electrode layer.

(11) A method of manufacturing a semiconductor device, the method including:

forming a gate insulating film on a gate electrode layer;

forming, in opposition to the gate electrode layer, a semiconductor layer on the gate insulating film; and

forming a source-drain electrode layer on the semiconductor layer and on the gate insulating film,

wherein a face, in opposition to the gate insulating film, of the semiconductor layer is located above a face of a section, located on the gate insulating film, of the source-drain electrode layer.

The present disclosure contains subject matter related to that disclosed in Japanese Priority Patent Application JP 2012-100543 filed in the Japan Patent Office on Apr. 26, 2012, the entire content of which is hereby incorporated by reference.

Although the technology has been described in terms of exemplary embodiments, it is not limited thereto. It should be appreciated that variations may be made in the described embodiments by persons skilled in the art without departing from the scope of the technology as defined by the following claims. The limitations in the claims are to be interpreted broadly based on the language employed in the claims and not limited to examples described in this specification or during the prosecution of the application, and the examples are to be construed as non-exclusive. For example, in this disclosure, the term “preferably”, “desirably” or the like is non-exclusive and means “preferably”, but not limited to. The use of the terms first, second, etc. do not denote any order or importance, but rather the terms first, second, etc. are used to distinguish one element from another. Moreover, no element or component in this disclosure is intended to be dedicated to the public regardless of whether the element or component is explicitly recited in the following claims.

1. A semiconductor device, comprising:
a gate electrode layer;
a gate insulating film provided on the gate electrode layer;
a semiconductor layer provided, in opposition to the gate electrode layer, on the gate insulating film; and
a source-drain electrode layer provided on the semiconductor layer and on the gate insulating film,
wherein a face, in opposition to the gate insulating film, of the semiconductor layer is located above a face of a section, located on the gate insulating film, of the source-drain electrode layer.

2. The semiconductor device according to claim 1, further comprising a raised section where the semiconductor layer is provided, the raised section being provided in a region, in opposition to the gate electrode layer, on the gate insulating film.

3. The semiconductor device according to claim 2, wherein the raised section includes a stepped section that is dug-down and provided at a drain-side section or at both of a source-side section and the drain-side section of the gate insulating film, the source-side section and the drain-side section being adjacent to the region, of the gate insulating film, in which the semiconductor layer is provided.

4. The semiconductor device according to claim 1, further comprising an insulating film provided on the gate insulating film,
wherein the semiconductor layer is provided in a region, in opposition to the gate electrode layer, of the insulating film, and
a drain-side section or both of a source-side section and the drain-side section of the insulating film is removed, the source-side section and the drain-side section being adjacent to the region, of the insulating film, in which the semiconductor layer is provided.

5. The semiconductor device according to claim 4, wherein the insulating film has a dielectric constant higher than a dielectric constant of the gate insulating film.

6. The semiconductor device according to claim 1, wherein the gate electrode layer has a size that covers, in plan view, the semiconductor layer.

7. The semiconductor device according to claim 1, further comprising a protecting film provided on the semiconductor layer,
wherein the source-drain electrode layer is provided on the protecting film.

8. The semiconductor device according to claim 1, wherein the semiconductor layer includes an organic semiconductor.

9. The semiconductor device according to claim 1, wherein the semiconductor layer includes an oxide semiconductor.

10. A display provided with a semiconductor device, the semiconductor device comprising:
a gate electrode layer;
a gate insulating film provided on the gate electrode layer;
a semiconductor layer provided, in opposition to the gate electrode layer, on the gate insulating film; and
a source-drain electrode layer provided on the semiconductor layer and on the gate insulating film,
wherein a face, in opposition to the gate insulating film, of the semiconductor layer is located above a face of a section, located on the gate insulating film, of the source-drain electrode layer.

11. A method of manufacturing a semiconductor device, the method comprising:
forming a gate insulating film on a gate electrode layer;
forming, in opposition to the gate electrode layer, a semiconductor layer on the gate insulating film; and
forming a source-drain electrode layer on the semiconductor layer and on the gate insulating film,
wherein a face, in opposition to the gate insulating film, of the semiconductor layer is located above a face of a section, located on the gate insulating film, of the source-drain electrode layer.
